(19) United States
(12) Patent Application Publication
(10) Pub. No.: US 2008/0131725 A1
(43) Pub. Date: Jun. 5, 2008

(54) Coated inserts for milling of compacted graphite iron

(75) Inventors: Emmanuel David, Sandviken (SE); Ingemar Hessman, Sandviken (SE)

Correspondence Address: DRINKER BIDDLE & REATH (DC), 1500 K STREET, N.W., SUITE 1100, WASHINGTON, DC, 20005-1209, US

(73) Assignee: SANDVIK INTELLECTUAL PROPERTY AB

(21) Appl. No.: 11/984,369

(22) Filed: Nov. 16, 2007

(30) Foreign Application Priority Data
Nov. 20, 2006 (SE) 0602457-4

(51) Int. Cl. B32B 15/04; C23C 16/00; B23P 15/28

(52) U.S. Cl. 428/627; 427/249.19; 407/114

(57) ABSTRACT

The present invention discloses coated inserts particularly useful for milling of compacted graphite iron under wet conditions at moderate cutting speeds comprising a cemented carbide body and a coating. The cemented carbide body comprises WC, from about 7.3 to about 7.9 wt-% Co and from about 1.0 to about 1.8 wt-% cubic carbides of Ta and Nb and a highly W-alloyed binder phase. The radius of the uncoated cutting edge is from about 25 to about 45 μm.

The coating comprises:
a first, less than about 1 μm, TiCxNyOz layer adjacent to the cemented carbide having a composition of x+y=1, x is greater than or equal to 0;
a second, from about 1 to about 2 μm, TiCₓN_{y}O_{z} layer having a composition of x greater than about 0.4, y greater than about 0.4 and z is less than about 0.1 and equal to or greater than zero;
a third, less than about 1 μm, TiCₓN_{y}O_{z} layer having a composition of x+y+z greater than or equal to about 1 and z greater than about 0;
an α-Al₂O₃-layer with a thickness of from about 2.1 to about 3.3 μm; and
a further from about 0.1 to about 2.5 μm, thick layer of TiN missing along the edge line.

### BACKGROUND OF THE INVENTION

The present invention relates to coated cemented carbide cutting tool inserts particularly useful for milling of compacted graphite iron (CGI) under wet and dry conditions at moderate to high cutting speeds.

Compacted graphite iron (CGI) sometimes also called vermicular iron, is a material becoming more and more interesting for environmental reasons in engine manufacturing. With 75% higher tensile strength and around 45% greater stiffness than alloyed grey cast iron, CGI is particularly suitable for complex components subjected to mechanical and/or thermal loading such as in diesel engine blocks and cylinder heads where cleaner emissions call for higher internal operating pressures. CGI allows the development of lighter, stronger engine blocks and heads.

Recent trends in CGI engine development have also been towards increased power density in the engine design. It is exactly what manufacturers want provided that the material can be machined quickly and efficiently with machining processes whose overall cost and cycle times match similar operations for grey cast iron and aluminum components.

CGI has a unique morphology, also called Coral structure, which gives strong adhesion properties between the compacted graphite and the iron matrix. This suppresses crack initiation and propagation in the material and provides increased mechanical properties relative to alloyed grey cast iron and improved thermal conductivity relative to ductile iron. Overall this adds up to improved mechanical properties and a material that is twice as strong as grey cast iron.

CGI can be produced with varying pearlite contents to suit the required application and this has implications for the machining process. More particularly, CGI for engine blocks and heads normally aims at a pearlite content of about 90 vol % and a nodularity of about 20 vol %.

The unique grain structure of CGI is particularly demanding on tool life as machining of CGI tends to demand higher cutting forces, i.e. temperature. It is hard to machine under the same conditions as for alloyed grey cast iron. The pearlitic content is the dominating factor influencing the tool life. Also the amount of carbides influences tool life but to a lower degree.

A dominating problem when machining CGI is the burr formation, which reduces tool life.

A general recommendation for milling of CGI is to do it under dry conditions, if you just consider machining and cost per component, (tool life).

However if you take in to consideration the reliability of the machine, it will be understood that the machine tool builder will not guarantee the functionality of the machine if it is used under dry conditions due to the fact that dry machining creates high temperature, chips, dust etc. High temperature, hot chips and dust might affect the machine and the components.

Due to those reasons, most of the milling of CGI is done as wet milling with a coolant even if the cost per component increases.

### OBJECTS AND SUMMARY OF THE INVENTION

It is an object of the present invention to provide a milling insert particularly useful at moderate to high speed milling of CGI which an ability to carry out these operations at cycle times and at a cost that match similar processes on alloyed cast grey iron under dry and wet conditions.

In one embodiment of the invention, there is provided a cutting tool insert comprising a cemented carbide body and a coating, said cemented carbide body comprising WC, from about 7.3 to about 7.9 wt-% Co and from about 1.0 to about 1.8 wt-% cubic carbides of Ta and Nb and a highly W-alloyed binder phase with a CW-ratio of from about 0.86 to about 0.94 and a radius of the uncoated cutting edge of from about 25 to about 45 μm, said coating comprising a first, less than about 1 μm, TiCₓN_{y}O_{z} layer adjacent to the cemented carbide having a composition of x+y=1, x is greater or equal to 0, a second, from about 1 to about 2 μm, TiCₓN_{y}O_{z} layer having a composition of x greater than about 0.4, y greater than about 0.4 and z less than about 0.1 and equal to or greater than zero, a third, less than about 1 μm, TiCₓN_{y}O_{z} layer having a composition where x+y+z is greater to or equal to about 1, preferably x+y+z=1, z is greater than 0, and preferably y is less than about 0.2, an α-Al₂O₃-layer with a thickness of from about 2.1 to about 3.3 μm and a further from about 0.1 to about 2.5 μm thick layer of TiN.

In another embodiment of the invention, there is provided a method of making an insert comprising a cemented carbide body and a coating, the WC-Co-based cemented carbide body comprising WC, from about 7.3 to about 7.9 wt-% Co and from about 1.0 to about 1.8 wt-% cubic carbides of Ta and Nb and a highly W-alloyed binder phase with a CW-ratio of from about 0.86 to about 0.94, the method comprising the steps of: treating the inserts to obtain an edge radius of from about 25 to about 45 μm, depositing by a CVD-method a first, less than about 1 μm TiCₓN_{y}O_{z} layer adjacent to the cemented carbide having a composition of x+y=1, x is greater than or equal to about 0, and z=0; depositing by a MTCVD-technique a second, from about 1 to about 2 μm, TiCₓN_{y}O_{z} layer having a composition of x greater than about 0.4, y greater than about 0.4 and z is equal to or greater than 0 and less than about 0.1, wherein the MTCVD-technique uses acetonitrile as a source of carbon and nitrogen for forming a layer in a temperature range of from about 700 to about 900° C.; depositing a third, less than about 1 μm TiCₓN_{y}O_{z} layer having a composition of x+y+z greater than or equal to about 1, preferably x+y+z=1, z is greater than about 0, and preferably y is less than about 0.2, deposited using known CVD-methods an α-Al₂O₃-layer with a thickness of from about 2.1 to about 3.3 μm; and depositing using known CVD-methods a further from about 0.1 to about 2.5 μm, thick layer of TiN.

In still another embodiment of the invention, there is provided a use of a cutting tool insert described above for dry or wet milling of compacted graphite iron at a cutting speed of from about 80 to about 280 m/min, depending on length of engagement and a feed of from about 0.1 to about 0.35 mm/tooth depending on cutting speed and insert geometry.

### DETAILED DESCRIPTION OF THE PREFERRED EMBODIMENTS

It has now surprisingly been found that by balancing the substrate and coating properties to meet the loads in the milling application, cutting tool insert have been obtained with excellent cutting performance when wet milling compacted graphite iron using fluid coolant or at dry conditions at moderate to high cutting speeds.

The cutting tool inserts according to the present invention show improved tool life. The criteria's for milling of CGI is normally surface finish of components, burrs, etc, depending on the presence of thermal cracks and flank wear. Surprisingly it has been found that the number of thermal cracks is reduced and the tool life is increased.

The cutting tool inserts according to the present invention have a cemented carbide body with a rather highly W-alloyed binder phase and with a well balanced chemical composition and grain size of the WC, TiCₓN_{y}-layer, an α-Al₂O₃-layer, and a TiN-layer with smooth cutting edges obtained by brushing the edges.

According to the present invention, coated cutting tool inserts are provided comprising a cemented carbide body with a composition of from about 7.3 to about ˜7.9 wt-% Co, preferably about 7.6 wt-% Co, from about 1.0 to about 1.8 wt-% cubic carbides, preferably from about 1.4 to about 1.7 wt-% cubic carbides of the metals Ta and Nb and balance WC. The average grain size of the WC is from about 1.5 to about 2.5 μm, preferably about 1.8 μm.

The cobalt binder phase is rather highly alloyed with W. The content of W in the binder phase is expressed as the

CW-ratio=magnetic-%Co/wt-%Co

where magnetic-% Co is the weight percentage of magnetic Co and wt-% Co is the weight percentage of Co in the cemented carbide. The CW-value is a function of the W content in the Co binder phase. A CW-value of about 1 corresponds to a low W-content in the binder phase and a CW-value of about from about 0.75 to about 0.8 corresponds to a high W-content in the binder phase.

According to the present invention, improved cutting performance is achieved if the cemented carbide body has a CW-ratio of from about 0.86 to about 0.94.

The radius of the uncoated cutting edge is from about 25 to about 45 μm.

The cemented carbide insert is at least partly coated with a from about 4.7 to about 6.8 μm thick coating including at least three layers of TiCₓN_{y}O_{z}. The TiCₓN_{y}O_{z}-layers have a total thickness of from about 2.1 to about 3.3 μm and comprise:

A first, less than about 1 μm, TiCₓN_{y}O_{z} layer adjacent to the cemented carbide having a composition of x+y=1, x is greater than or equal to about 0, preferably x is less than about 0.2, and z=0;

A second, from about 1 to about 2 μm, TiCₓN_{y}O_{z} layer having a composition of x greater than about 0.4, y greater than about 0.4 and z being equal to or greater than zero and less than about 0.1, preferably z=0;

A third, less than about 1 μm, TiCₓN_{y}O_{z} layer adjacent to the α-Al₂O₃-layer having a composition of x+y+z greater than or equal to about 1, preferably x+y+z=1, z is greater than 0, preferably z is greater than about 0.2, and preferably y is less than about 0.2;

An α-Al₂O₃-layer with a thickness of from about 2.1 to about 3.3 μm;

A further from about 0.1 to about 2.5 μm, preferably about 1.2 μm thick layer of TiN, preferably missing along the cutting edge. The underlying alumina layer may also be partly missing along the cutting edge.

The present invention also relates to a method of making coated cutting tool inserts of a cemented carbide body with a composition of from about 7.3 to about 7.9 wt-% Co, preferably about 7.6 wt-% Co, from about 1.0 to about 1.8 wt-% cubic carbides, preferably from about 1.4 to about 1.7 wt-% cubic carbides of the metals Ta and Nb and balance WC. The average grain size of the WC is from about 1.5 to about 2.5 μm, preferably about 1.8 μm.

After blasting the inserts to an edge radius of from about 25 to about 45 μm the following coating is deposited:

A first, less than about 1 μm, TiCₓN_{y}O_{z} layer adjacent to the cemented carbide having a composition of x+y=1, x greater than about or equal to about 0, preferably x is less than about 0.2, and z=0 using known CVD-methods,

A second, from about 1 to about 2 μm, TiCₓN_{y}O_{z} layer having a composition of x greater than about 0.4, y greater than about 0.4 and z being equal to or greater than about zero and less than about 0.1, preferably z=0, using preferably MTCVD-technique, using acetonitrile as the carbon and nitrogen source for forming the layer at a temperature of from about 700 to about 900° C. The exact conditions, however, depend to a certain extent on the design of the equipment used;

A third, less than about 1 μm, TiCxNyOz layer adjacent to the α-Al₂O₃-layer having a composition of x+y+z greater than or equal to about 1, preferably x+y+z=1 and z is greater than about 0, preferably z is greater than about 0.2, and preferably y is less than about 0.2;
An α-Al₂O₃-layer with a thickness of from about 2.1 to about 3.3 μm using known CVD-methods; and
a further, from about 0.1 to about 2.5 μm, preferably about 1.2 μm thick layer of TiN.

The edge line is brushed with brushes based on, e.g., SiC as disclosed, e.g., in U.S. Pat. No. 5,861,210. The TiN-layer is preferably removed along the cutting edge and the alumina layer may be partly removed along the cutting edge.

The invention also relates to the use of cutting tool inserts according to the above for milling of compacted graphite iron, either dry milling or wet milling using fluid coolant, at a cutting speed of from about 80 to about 280 m/min, depending on length of engagement, and a feed of from about 0.1 to about 0.35 mm/tooth depending on cutting speed and insert geometry.

The invention is additionally illustrated in connection with the following examples, which are to be considered as illustrative of the present invention. It should be understood, however, that the invention is not limited to the specific details of the examples.

### Example 1

A. Cemented carbide milling inserts type TNEF 1204AN-KX in accordance with the invention with the composition 7.6 wt-% Co, 1.25 wt-% TaC, 0.30 wt-% NbC and balance WC with average grain size of 1.8 μm, with a binder phase alloyed with W corresponding to a CW-ratio of 0.9 were coated as follows after having been blasted to an edge radius of 35 μm:

a first layer of 0.5 μm TiC_{0.05}N_{0.95} using known CVD method using a reaction mixture consisting of TiCl₄, H₂ and N₂,

a second layer of 1.7 μm columnar TiC_{0.55}N_{0.45} using the well-known MTCVD-technique, temperature 885-850° C. and CH₃CN as the carbon/nitrogen source,

a third, bonding layer of 0.5 μm TiC_{0.5}O_{0.5} with needle shaped grains,

a fourth layer consisting of 2.7 μm α-Al₂O₃ and finally a top layer of about 1.3 μm TiN using known CVD-technique. XRD-measurements confirmed that the Al₂O₃-layer consisted to 100% of the α-phase.

After the coating cycle the edge line of the inserts was subjected to a brushing operation using SiC brushes.

B. Sandvik GC4020 commercial grade

C. Cemented carbide milling inserts of style TNEF1204AN-KM and with the composition 6% Co and balance WC and an edge radius of 50 μm were coated with the same coating as A.

### Example 2

Inserts A, B and C were subjected to the following performance test:

| | |
|---|---|
| Operation: | Face milling - roughing |
| Work-piece: | Diesel engine block top face |
| Material: | CGI 85% pearlite and 23% nodularity |
| Tool: | Sandvik Coromant R260.31-315 |
| Criterion: | Surface finish (burr formation). |

Cutting data

| | |
|---|---|
| Cutting speed: | Vc = 200 m/min |
| Feed rate/tooth: | Fz = 0.20 mm/rev |
| Depth of cut: | Ap = 4 mm |

Dry condition

| Results: | Tool-life, number of engine blocks | |
|---|---|---|
| Grade A: | (invention) | 874 |
| Grade B: | Sandvik GC 4020 | 695 |
| Grade C: | Reference | 456 |

### Example 3

Inserts A, B and C were subjected to the following performance test:

| | |
|---|---|
| Operation: | Face milling - roughing |
| Work-piece: | Cylinder head |
| Material: | CGI 90% Pearlitic and nodularity 17% |
| Tool: | Sandvik Coromant R260.31-250 |
| Criterion: | Surface finish: (Burr formation) |

Cutting data

| | |
|---|---|
| Cutting speed: | Vc = 178 m/min |
| Feed rate/tooth: | Fz = 0.18 mm/rev |
| Depth of cut: | Ap = 3.5 mm |

Wet condition

| Insert-style: | TNEF 1204AN-KX | |
|---|---|---|
| Results: | Tool-life, number of cylinder heads | |
| Grade A: | (invention) | 748 |
| Grade B: | Sandvik GC 4020 | 576 |
| Grade C: | Reference | 487 |

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

1. A cutting tool insert comprising a cemented carbide body and a coating, said cemented carbide body comprising WC, from about 7.3 to about 7.9 wt-% Co and from about 1.0 to about 1.8 wt-% cubic carbides of Ta and Nb and a highly W-alloyed binder phase with a CW-ratio of from about 0.86 to about 0.94 and a radius of the uncoated cutting edge of from about 25 to about 45 μm, said coating comprising:
a first, less than about 1 μm, TiCₓN_{y}O_{z} layer adjacent to the cemented carbide having a composition of x+y=1, x is greater than or equal to 0;
a second, from about 1 to about 2 μm, TiCₓN_{y}O_{z} layer having a composition of x greater than about 0.4, y greater than about 0.4 and z is less than about 0.1 and equal to or greater than 0;
a third, less than about 1 μm, TiCₓN_{y}O_{z} layer having a composition where x+y+z is greater than or equal to about 1 and z greater than about 0;
an α-Al₂O₃-layer with a thickness of from about 2.1 to about 3.3 μm; and
a further from about 0.1 to about 2.5 μm thick layer of TiN.

2. The insert of claim 1 wherein the cemented carbide contains from about 1.4 to about 1.7 wt-% carbides of Ta and Nb.

3. The insert of claim 1 wherein the outermost TiN-layer is missing along the cutting edge.

4. The insert of claim 1 wherein in said first layer x is less than about 0.2 and z is equal to about 0, in said second layer z is equal to about 0, in said third layer z is greater than about 0.2, x+y+z=1 and y less than about 0.2, and said layer of TiN is about 1.2 μm thick.

5. Method of making an insert comprising a cemented carbide body and a coating, the WC-Co-based cemented carbide body comprising WC, from about 7.3 to about 7.9 wt-% Co and from about 1.0 to about 1.8 wt-% cubic carbides of Ta and Nb and a highly W-alloyed binder phase with a CW-ratio of from about 0.86 to about 0.94, the method comprising the steps of:
treating the inserts to obtain an edge radius of from about 25 to about 45 μm,
depositing by a CVD-method a first, less than about 1 μm, TiCₓN_{y}O_{z} layer adjacent to the cemented carbide having a composition of x+y=1, x is greater than or equal to about 0,
depositing by a MTCVD-technique a second, from about 1 to about 2 μm, TiCₓN_{y}O_{z} layer having a composition of x greater than about 0.4, y greater than about 0.4 and z is equal to or greater than about 0 and less than about 0.1, wherein the MTCVD-technique uses acetonitrile as a source of carbon and nitrogen for forming a layer in a temperature range of from about 700 to about 900° C.;
depositing a third, less than about 1 μm, TiCₓN_{y}O_{z} layer having a composition of x+y+z greater than or equal to about 1 and z greater than about 0,
depositing using known CVD-methods an α-Al₂O₃-layer with a thickness of from about 2.1 to about 3.3 μm; and
depositing using known CVD-methods a further from about 0.1 to about 2.5 μm, thick layer of TiN.

6. Method of claim 5 wherein said cemented carbide body contains from about 1.4 to about 1.7 wt-% carbides of Ta and Nb.

7. Method of claim 5 further comprising removing the outermost TiN-layer is removed along the cutting edge by brushing with SiC brushes.

8. The method of claim 5 wherein in said first layer x is less than 0.2 and z is equal to about 0.2; in said second layer z is equal to about 0, in said third layer z is greater than about 0.2, x+y+z=1 and y less than about 0.2, and said layer of TiN is about 1.2 μm thick.

9. Use of a cutting tool insert according to claim 1 for dry or wet milling of compacted graphite iron at a cutting speed of from about 80 to about 280 m/min, depending on length of engagement and a feed of from about 0.1 to about 0.35 mm/tooth depending on cutting speed and insert geometry.
